(19) United States
(12) Patent Application Publication
(10) Pub. No.: US 2025/0048748 A1
(43) Pub. Date: Feb. 6, 2025

(54) METHOD FOR MANUFACTURING PHOTOVOLTAIC MODULE

(71) Applicant: KOREA UNIVERSITY RESEARCH AND BUSINESS FOUNDATION, Seoul (KR)

(72) Inventors: Donghwan KIM, Yangpyeong-gun (KR); Yoonmook KANG, Seoul (KR); Hae-Seok LEE, Seoul (KR); Yongseok JUN, Seoul (KR); Chanyong LEE, Seoul (KR); Jongwon KO, Seoul (KR)

(73) Assignee: KOREA UNIVERSITY RESEARCH AND BUSINESS FOUNDATION, Seoul (KR)

(21) Appl. No.: 18/577,372

(22) PCT Filed: Jun. 22, 2022
(86) PCT No.: PCT/KR2022/008821

§ 371 Date: Aug. 7, 2024

(30) Foreign Application Priority Data
Jul. 6, 2021 (KR) 10-2021-0088266

(51) Int. Cl. H01L 31/05; H01L 31/048; H01L 31/18

(52) U.S. Cl. CPC H01L 31/0508; H01L 31/048; H01L 31/1876

(57) ABSTRACT

Disclosed is a method for manufacturing a photovoltaic module including forming a solar cell assembly by connecting a plurality of solar cells in an alignment direction in series, forming a plurality of solar cell units by cutting the solar cell assembly along a cutting line in a direction being different from the alignment direction, and disposing the plurality of solar cell units in an encapsulation member such that angles defined by a height direction of the encapsulation member and upper surfaces of the solar cell units are 30 degrees to 90 degrees.

### TECHNICAL FIELD

The present disclosure relates to a method for manufacturing a photovoltaic module.

The present disclosure is derived from the research conducted as part of the Ministry of Trade, Industry and Energy's new and renewable energy core technology development (R&D) (Project identification number: 1415169068, Research management agency: Korea Institute of Energy Technology Evaluation and Planning, Research project name: Development of a transparent solar cell platform that is easy to expand, Host organization: Korea University Industry-Academic Cooperation Foundation, research period: Jun. 1, 2020 to May 31, 2021, contribution rate: 1/2).

Furthermore, the present disclosure is derived from the research conducted as part of the Ministry of Trade, Industry and Energy's energy international cooperative research (R&D) (Project identification number: 1415168343, Research management agency: Korea Institute of Energy Technology Evaluation and Planning, Research project name: Development of a charge-selective silicon solar cell for 24.5% level efficiency for mass-production of high-efficiency solar cells and module technology, Host organization: Korea University Industry-Academic Cooperation Foundation, research period: Apr. 1, 2020 to Jan. 31, 2021, contribution rate: 1/2).

Meanwhile, there is no property interest of the Korean government in any aspect of the present disclosure.

### BACKGROUND ART

An element that converts energy of photons generated from the sun into electrical energy through a photoelectric effect is called a solar cell, and an assembly of two or more solar cells connected in series or parallel in a single circuit is called a photovoltaic module.

A core material of solar cells may be referred to as a light absorption layer that exhibits a photoelectric effect, and the material includes silicon, copper indium gallium selenide (CIGS), cadmium telluride (CdTe), a III-V group element composite material, a photoactive organic material, perovskite, and quantum dots.

In general, a solar power system is a system that converts light energy into electrical energy by using solar cells, and is used as an independent power source for general homes or industrial purposes, or as an auxiliary power source in connection with a commercial AC power system.

The solar cell is manufactured by a p-n junction of semiconductor materials, and uses a photovoltaic effect, which causes a small amount of currents to flow when receiving light, and most ordinary solar cells include a p-n junction diode of a larger area, and when an electromotive force generated at opposite ends of the p-n junction diode is connected to an external circuit, the diode acts as a unit solar cell. Because the electromotive force of the solar cell as described above is small, it is used by connecting multiple solar cells to form a photovoltaic module with an appropriate electromotive force.

Grid-connected solar power systems, which are commonly used on the exteriors of buildings, include a plurality of solar cell arrays that convert solar energy into electrical energy, and DC power, which is the electrical energy obtained from the solar cell arrays through conversion, and an inverter that converts DC power to AC power and supplies it to users.

In the solar power system, installation of solar cell arrays, which are installed to obtain solar energy, is the most important element in constituting the system, and the solar cell arrays are installed on a separately secured site or on the roof of a building.

Accordingly, a separate space has to be secured to install a solar power system in a building, and because a cooling tower that constitutes a cooling apparatus is typically installed on the rooftop of a building, a space for installing a solar cell array is narrow and limited whereby installation of the solar cell array is limited and an installation work becomes difficult.

To compensate for these shortcomings, there are cases, in which solar power systems are applied to window systems installed for lighting and ventilation of buildings.

However, the conventional solar power system has a complicated installation structure, making installation and expansion thereof difficult.

### DETAILED DESCRIPTION OF THE INVENTION

### Technical Problem

The present disclosure provides a photovoltaic module that may be easily installed and expanded, and by which disposition of a plurality of solar cells may be easily controlled.

Meanwhile, the technical problems sought to be achieved in the present disclosure are not limited to the technical problems mentioned above, and other technical problems not mentioned may be clearly understood by those skilled in the art, to which the present disclosure pertains, from the description below.

### Technical Solution

A method for manufacturing a photovoltaic module includes forming a solar cell assembly by connecting a plurality of solar cells in an alignment direction in series, forming a plurality of solar cell units by cutting the solar cell assembly along a cutting line in a direction being different from the alignment direction, and disposing the plurality of solar cell units in an encapsulation member such that angles defined by a height direction of the encapsulation member and upper surfaces of the solar cell units are 30 degrees to 90 degrees.

Furthermore, the forming of the solar cell assembly may include forming joining parts in joining areas of the adjacent solar cells, and connecting the plurality of solar cells in the alignment direction in series.

Furthermore, in the forming of the joining parts, each of the joining parts may have a plurality of ball shapes disposed to be spaced apart from each other.

Furthermore, in the forming of the joining parts, the joining parts may be spaced apart from the area of the cutting line.

Furthermore, in the forming of the plurality of solar cell units, widths of the plurality of formed solar cell units may be the same.

Furthermore, the plurality of solar cell units may be connected to each other in parallel through a pair of terminals.

Furthermore, the solar cell units may be arranged in parallel to a horizontal surface.

Furthermore, the method may further include electrically connecting the solar cell units spaced apart from each other in the height direction through conductive members.

Furthermore, the solar cell units may include a first solar cell disposed on one side, and a second solar cell electrically connected to the first solar cell and disposed on an opposite side to extend, the first solar cell may include a front electrode, an n-type semiconductor layer, a p-type semiconductor layer, and a rear electrode, which are sequentially laminated, and the second solar cell may include an n-type semiconductor layer connected to the rear electrode of the first solar cell, a p-type semiconductor layer, and a terminal electrode connecting the n-type semiconductor layer and the conductive member.

Furthermore, the solar cell units may include a first solar cell disposed on one side, and a second solar cell electrically connected to the first solar cell and disposed on an opposite side to extend, the first solar cell may include a front electrode, an n-type semiconductor layer, a p-type semiconductor layer, and a rear electrode, which are sequentially laminated, the second solar cell may include an n-type semiconductor layer connected to the rear electrode of the first solar cell, a p-type semiconductor layer, and a terminal electrode connecting the p-type semiconductor layer and the conductive member, and an opposite end of the terminal electrode may extend to an opposite side of an opposite end of the p-type semiconductor layer.

Furthermore, each of the plurality of solar cell unit may include a first solar cell disposed on one side, and a second solar cell electrically connected to the first solar cell and disposed on an opposite side to extend, the first solar cell may include a front electrode, a n-type semiconductor layer, a p-type semiconductor layer, and a rear electrode, which are sequentially laminated, and the conductive member may include a support part extending in a height direction, a plurality of grip parts extending from the support part to the solar cell units, and a plurality of grip parts configured to grip the first solar cell, and a conductive part electrically connected to the front electrode of the first solar cell.

### Advantageous Effects of the Invention

According to the embodiments of the present disclosure, the photovoltaic module may be easily installed, and the disposition of the plurality of solar cells may be easily controlled.

Meanwhile, the effects that may be obtained from the present disclosure are not limited to the effects mentioned above, and other effects not mentioned may be clearly understood by those skilled in the art, to which the present disclosure pertains, from the description below.

### DESCRIPTION OF THE DRAWINGS

FIG. 1 is a flowchart illustrating a method for manufacturing a photovoltaic module according to a first embodiment of the present disclosure.

FIGS. 2 to 12 are cross-sectional views sequentially illustrating a process according to a method for manufacturing a photovoltaic module according to a first embodiment of the present disclosure.

FIG. 13 is an exemplary view illustrating a photovoltaic module according to a second embodiment of the present disclosure.

FIG. 14 is an exemplary view illustrating a photovoltaic module according to a third embodiment of the present disclosure.

FIG. 15 is an exemplary view illustrating a photovoltaic module according to a fourth embodiment of the present disclosure.

FIG. 16 is an exemplary view illustrating a photovoltaic module according to a fifth embodiment of the present disclosure.

FIGS. 17 to 20 are exemplary views illustrating a photovoltaic module sequentially manufactured according to a sixth embodiment of the present disclosure.

FIGS. 21 to 24 are exemplary views illustrating a photovoltaic module sequentially manufactured according to a seventh embodiment of the present disclosure.

FIG. 25 is an exemplary view illustrating a photovoltaic module according to an eighth embodiment of the present disclosure.

### BEST MODE

Hereinafter, embodiments of the present disclosure will be described in more detail with reference to the attached drawings. The embodiments of the present disclosure may be modified in various forms, and the scope of the present disclosure should not be construed as being limited to the following embodiments. The embodiments are provided to more completely describe the present disclosure to those skilled in the art. Therefore, the shapes of elements in the drawings are exaggerated to emphasize clearer description.

The configuration of the invention to clarify the solution to the problem to be solved by the present disclosure will be described in detail with reference to the accompanying drawings based on preferred embodiments of the present disclosure, and the reference numerals to the components in the drawings will be the same even if they are in different drawings, and it is stated in advance that the components of other drawings may be cited if necessary when describing the relevant drawings.

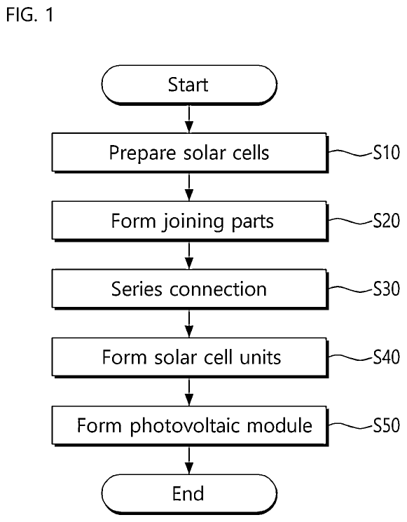

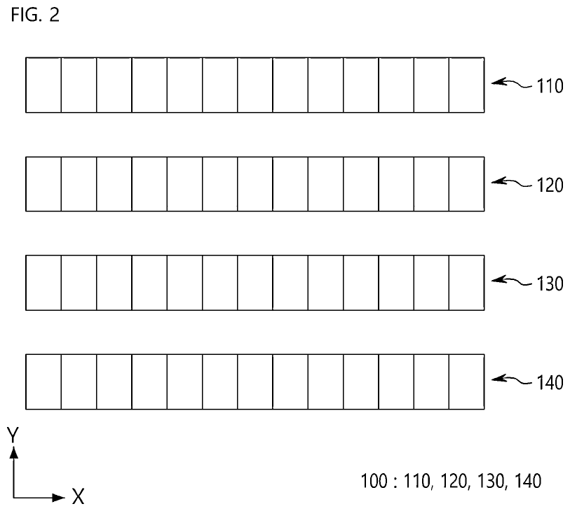

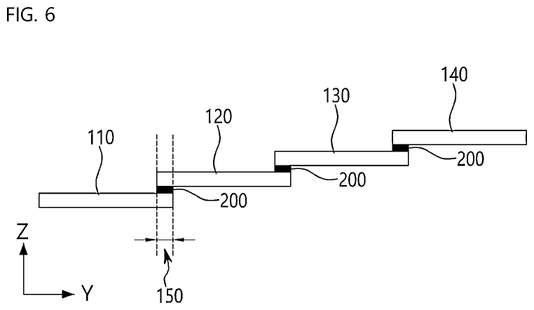

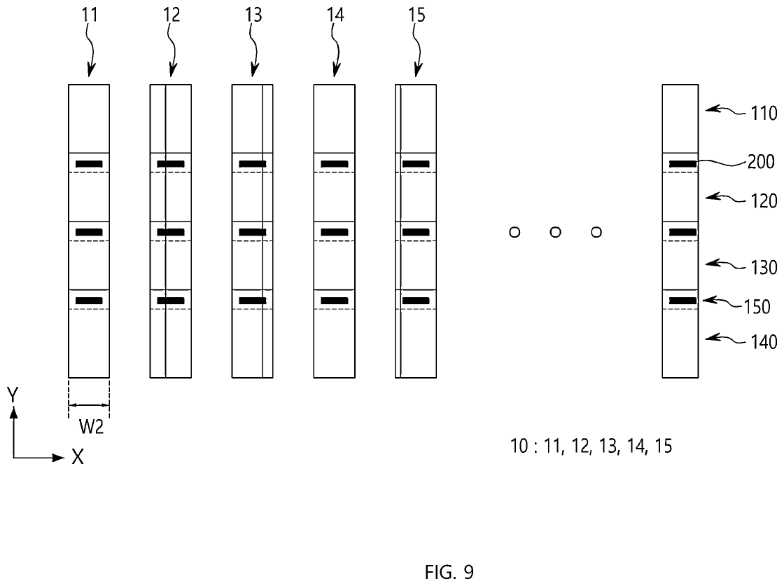

FIG. 1 is a flowchart illustrating a method for manufacturing a photovoltaic module according to a first embodiment of the present disclosure, and FIGS. 2 to 12 are cross-sectional views sequentially illustrating a process according to the method for manufacturing a photovoltaic module according to the first embodiment of the present disclosure.

First, referring to FIG. 1, the method for manufacturing a photovoltaic module according to the first embodiment of the present disclosure may include a solar cell preparing operation S10, a joining part forming operation S20, a series connection operation S30, a solar cell unit forming operation S40, and a solar cell module forming operation S50.

Referring to FIG. 2, in the solar cell preparing operation S10, a plurality of solar cells 100, 110, 120, 130, and 140 each provided with a front electrode and a rear electrode are prepared, and the plurality of solar cells 100 may be aligned in a first direction (the “Y” axis direction). Here, the first direction (the “Y” axis direction) also may be used as an alignment direction.

Each of the solar cells 100, 110, 120, 130, and 140, for example, may include a substrate, an emitter that is formed on a front surface of the substrate, which is an input surface, to which light is input, an anti-reflection film that is formed on the emitter, a plurality of passivation layers that are formed on a rear surface of the substrate, which is opposite to the front surface of the substrate, a plurality of front electrodes that are electrically connected to the emitter, a rear electrode that is formed on the plurality of passivation layers and the substrate, and a plurality of rear electric field layers that are formed between the rear electrode and the substrate.

The substrate may be a semiconductor formed of silicon of a first conductivity type, for example, an n-type or p-type conductivity type, and the emitter may be impurities of a second conductivity type that is opposite to the conductivity type of the substrate, for example, a p-type or an n-type, and may form a p-n junction with the semiconductor substrate.

The anti-reflection film may be formed by depositing a silicon nitride film (SiNx) or a silicon oxide film (SiOx) on the emitter, and the plurality of passivation layers are formed on the rear surface of the substrate, and have function to reduce a recombination rate of charges near the rear surface of the substrate.

The plurality of front electrodes may be formed on the emitter, may be electrically connected to the emitter, may be aligned in a predetermined direction to be spaced apart from each other, and may collect charges that have moved toward the emitter, such as holes/electrons to output them to an external device (load), may include at least one selected from the group consisting of nickel (Ni), copper (Cu), silver (Ag), aluminum (Al), tin (Sn), zinc (Zn), indium (In), titanium (Ti), gold (Au), and a combination thereof, and the front electrode may be formed of silver (Ag).

The rear electrode is formed of a conductive material, and may be formed integrally with the plurality of passivation layers on the rear surface of the substrate, and may include nickel (Ni), copper (Cu), silver (Ag), aluminum (Al), tin (Sn), and zinc (Zn), indium (In), titanium (Ti), gold (Au), and a combination thereof.

A rear electric field layer may be formed between the rear electrode and the substrate, and may function to hinder movement of holes/electrons toward the rear surface of the substrate to prevent the electrons and the holes from being recombined on the rear surface of the substrate and disappearing.

Meanwhile, in detail, the type of solar cells 100 applied in the present disclosure is not limited, but silicon solar cells and the like may be applied in the present disclosure.

That is, the silicon solar cells may be classified variously depending on the type and the structure of the used substrate, and depending on crystal characteristics of a light absorption layer, silicon solar cells may be broadly classified into multicrystalline and single crystalline silicon solar cells.

A single crystalline solar cell that is a representative silicon solar cell is a solar cell formed with a single crystalline silicon wafer as a substrate. In addition, the silicon solar cells may be manufactured with a multi-junction structure, such as a double junction structure (tandem), in which a solar cell that absorbs light of a different wavelength is laminated on another silicon solar cell, or a triple junction structure, in which a solar cell that absorbs light of another wavelength is further laminated thereon, or may be manufactured with a hybrid structure whereby a conversion efficiency is increased a level of a typical silicon solar cell or more.

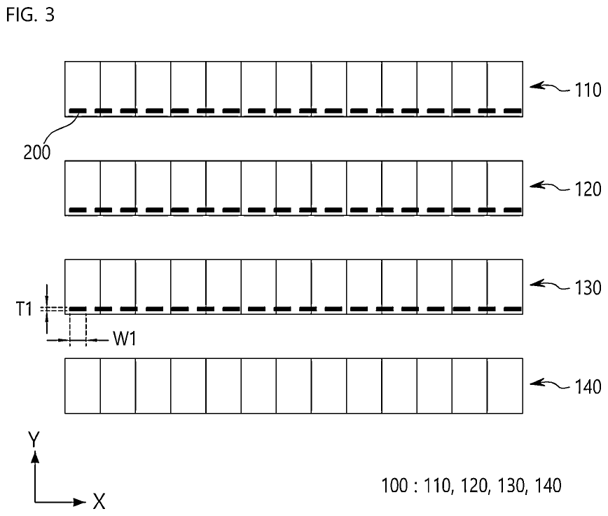

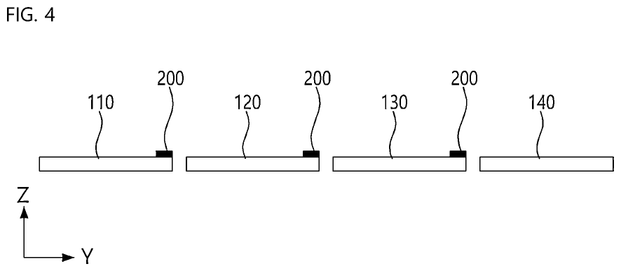

Referring to FIGS. 3 and 4, in the joining part forming operation S20, the joining parts 200 are formed at ends of the solar cells 110, 120, and 130 excluding the solar cell 140 located at an uppermost end of the plurality of solar cells 110, 120, 130, and 140 that are to be joined.

The joining parts 200 may be formed of a conductive adhesive, and a plurality of joining parts 200 may be disposed in a shape of balls that are spaced apart from each other along a second direction (the “X” axis direction) at the ends of the single solar cells 110, 120, and 130.

Each of the joining parts 200 may have a first thickness T1 and a first width W1. Here, the first thickness T1 may be defined as a thickness in the first direction (the “Y” axis direction), and the first width W1 may be defined as a width in the second direction (the “X” axis direction).

Meanwhile, the joining parts 200 may include metal solder balls, and for example, may be formed of eutectic solder (Sn37Pb), high lead solder (Sn95Pb), or lead-free solder (SnCu, SnAg, SnAgCu, SnAgBi, SnAgBiIn, SnAgZn, AnZn, SnBi, SnIn, and the like).

Furthermore, the joining part 200 is, among the conductive adhesives on the market, a product with a high conductivity and an appropriate viscosity that are suitable for the present disclosure, and for example, EL-3012, EL-3556, EL-3653, and EL-3655 of SKC Panacol and CE3103WLV and CA3556HF of Henkel may be applied, and for example, an adhesive with a viscosity of 28,000˜35,000 mPa·s (cP) at 25° C., as electrical properties, a volume resistivity of 0.0025 Ω·cm, and a curing temperature of 130˜150° C., and a curing time of 25 to 35 seconds is applied. Furthermore, a conductive filler in the conductive adhesive may include at least one material selected from Au, Pt, Pd, Ag, Cu, Ni, and carbon. However, the curing time and the temperature of the conductive adhesive may be changed depending on the type of the used adhesive, an application range and a thickness of the adhesive, and the like.

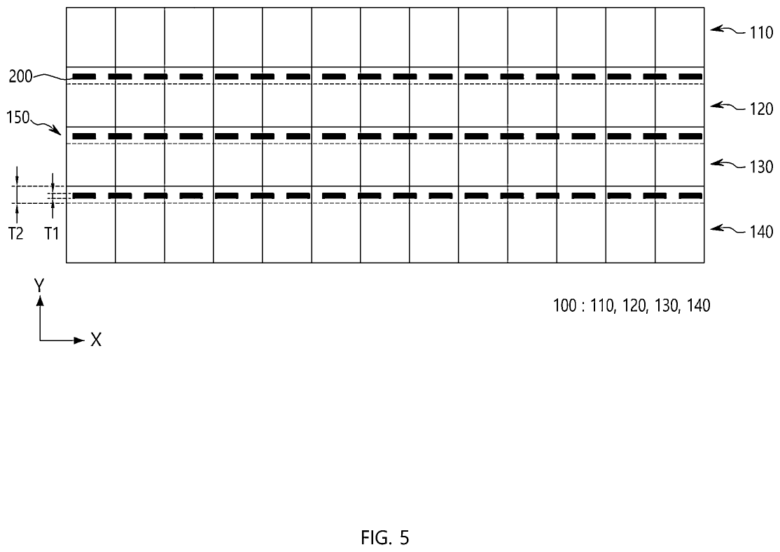

Referring to FIGS. 5 to 7, in the series connection step (S30), the plurality of solar cells 100 that are aligned in the first direction (the “Y” axis direction) form an overlapping area 150 and are arranged to be joined to each other. For example, in the series connection step S30, the plurality of solar cells 100 may be shingled.

For example, an opposite end (the rear electrode) of the second solar cell 120 overlaps one end (the front electrode) of the first solar cell 110, and an opposite end (the rear electrode) of the third solar cell 130 overlaps one end (the front electrode) of the second solar cell 120, and overlaps an opposite end (the rear electrode) of the fourth solar cell 140 on one end (the front electrode) of the third solar cell 130.

Here, the overlapping area 150 may have a second thickness T2 that is greater than a first thickness T1 of the joining part 200 in the first direction (the “Y” axis direction). Through this, when the adjacent solar cells 100 are joined to each other in the overlapping area 150, the joining part 200 may be prevented from being extracted to an outside of the overlapping area 150.

Thereafter, through a curing process, and the like, the adjacent solar cells 100 may be firmly attached through the joining part 200.

Through this, the plurality of solar cells 110, 120, 130, and 140 may be connected to each other in series.

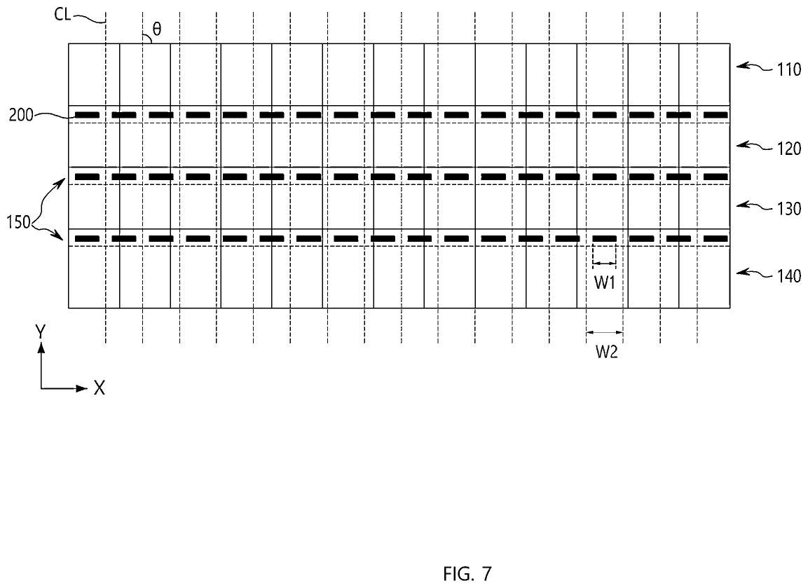

Hereinafter, a series connection relationship of the plurality of solar cells 110 and 120 will be described in more detail with reference to FIG. 7.

First, referring to FIG. 7A, each of the plurality of solar cells 110 and 120 connected in series next to each other includes a front electrode 111 (e.g., a − electrode), an n-type semiconductor layer 112, and a p-type semiconductor layer 113, and a rear electrode 114 (e.g., a + electrode).

In detail, the front electrode 111 may be disposed on one side of a front surface of the p-n junction layers 112 and 113, and the rear electrode 114 may be disposed on an opposite side of a rear surface of the p-n junction layers 112 and 113. That is, the rear electrode 114 of the first solar cell 110 and the front electrode 111 of the second solar cell 120 may be connected to each other through the joining part 200.

Furthermore, referring to FIG. 7B, each of the plurality of solar cells 110 and 120 connected in series next to each other includes the front electrode 111 (e.g., the − electrode), the n-type semiconductor layer 112, and the p-type semiconductor layer 113, and a conductive substrate 115 (e.g., the + electrode).

In detail, the front electrode 111 may be disposed on one side of the front surface of the p-n junction layers 112 and 113, and the conductive substrate 115 may be disposed on the entire rear surface of the p-n junction layers 112 and 113. That is, the conductive substrate 115 of the first solar cell 110 and the front electrode 111 of the second solar cell 120 may be connected to each other through the joining part 200.

Furthermore, referring to FIG. 7C, each of the plurality of solar cells 110 and 120 connected in series next to each other includes a front electrode 116 (e.g., a − electrode), an n-type semiconductor layer 112, and a p-type semiconductor layer 113, and a rear electrode 117 (e.g., a + electrode), and the plurality of solar cells 110 and 120 may be disposed together on the transparent substrate 118.

Here, the front electrode 116 may be disposed to surround the front surface and the opposite surface of the n-type semiconductor layer 112. Through this, the opposite ends of the front electrodes 116 of the adjacent first solar cell 110 on the substrate 118 may be connected to the rear electrodes 117 of the adjacent second solar cell 120. Meanwhile, in this case, the joining part may be formed, but a separate joining part may not be formed.

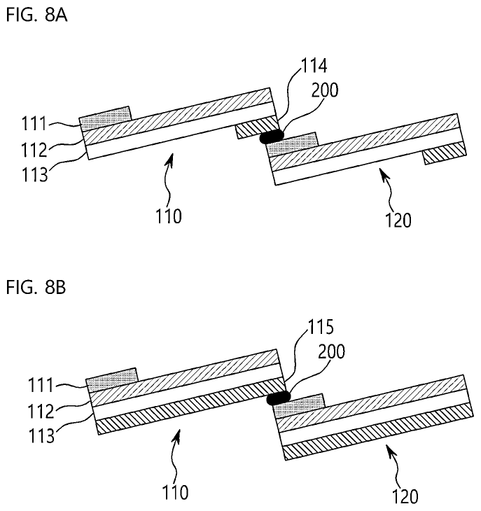

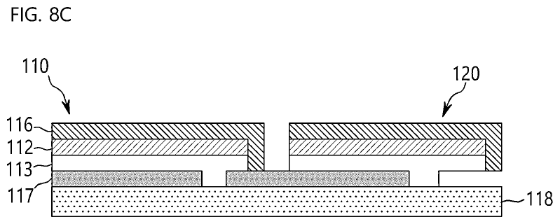

Referring to FIGS. 8 to 11, in the solar cell unit forming operation (S40), a solar cell assembly are divided into a plurality of solar cell units 10, 11, 12, 13, 14, and 15 through a plurality of cutting lines CL that are formed in a direction that is different from the first direction (the “Y” axis direction) (the alignment direction).

Here, each of the solar cell units 10, 11, 12, 13, 14, and 15 may include a plurality of divided solar cells 110, 120, 130, and 140. That is, each of the solar cell units 10, 11, 12, 13, 14, and 15 may have a plurality of solar cells 110, 120, 130, and 140 that are connected to each other in series.

Meanwhile, it is preferable that the plurality of cutting lines CL are disposed to be spaced apart from each other in the second direction (the “X” axis direction). That is, it is preferable that an angle “0” defined by the side surfaces of the solar cells 110, 120, 130, and 140 and the cutting line CL is a right angle.

Through this, the solar cell units 10, 11, 12, 13, 14, and 15 divided along the cutting line CL may have a rectangular shape.

It is preferable that cutting along the cutting line CL is performed by mechanical cutting (a laser beam or a diamond blade). Of course, it may be divided into solar cell units 10, 11, 12, 13, 14, and 15 through chemical etching along the cutting line CL.

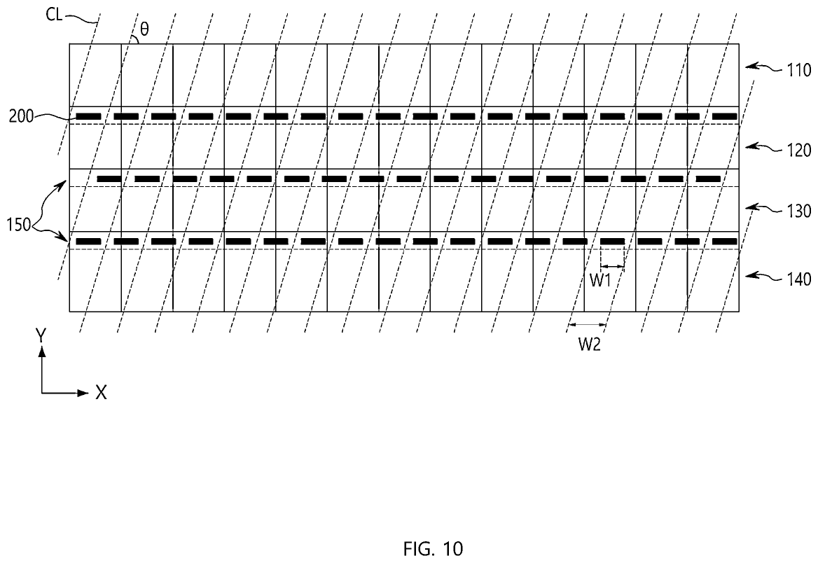

Meanwhile, as illustrated in FIG. 10, the angle “0” defined by the side surfaces of the solar cells 110, 120, 130, and 140 and the cutting line CL may be an acute angle, and the solar cell units 10, 11, 12, 13, 14, and 15 of various form may be formed by diagonally forming the cutting line CL.

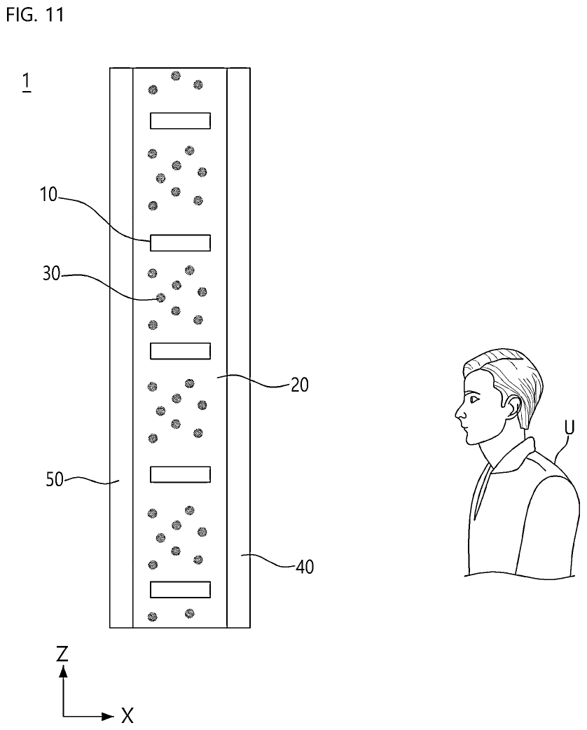

Meanwhile, as illustrated in FIGS. 8 and 11, an interval between the cutting lines CL has a second width W2, and the second width W2 is formed to be greater than the first width W1.

Meanwhile, as illustrated in FIGS. 8 and 10, the joining part 200 is not disposed in an area, in which each cutting line CL is to be formed. That is, the adjacent joining parts 200 may be spaced apart from each other, in the area, in which the cutting line CL is to be formed.

Through this, the joining part 200 is not damaged by the cutting line CL during the cutting process, and the cutting device may be prevented from being damaged by the joining parts 200 during the cutting process whereby a reliability of equipment and products may be improved.

Thereafter, referring to FIG. 11, the divided solar cell units 10, 11, 12, 13, 14, and 15 are arranged in a horizontal direction to manufacture the photovoltaic module 1.

The photovoltaic module 1 may include the solar cell units 10, an encapsulation member 20, a first substrate 40, a scattering part 30, and a second substrate 50.

The plurality of solar cell units 10 may be disposed to be inserted into one side of the encapsulation member 20.

It is preferable that the encapsulation member 20 is formed of a material that is transparent, flexible to be easy to change shape, and cured by heat or a UV ray.

For example, the encapsulation member 20 may be formed of an EVA material. However, in the present disclosure, the encapsulation member 20 is not limited to the EVA, and any material available as the encapsulation member of the photovoltaic module may be used.

Meanwhile, the encapsulation member 20 may prevent corrosion due to penetration of moisture and may protect the plurality of solar cells 110 from impacts. The encapsulation member 20 may be formed of a material, such as ethylene vinyl acetate (EVA), polyolefin (PO), an ionomer, polyvinyl butyral (PVB), and a silicone resin.

The plurality of solar cells 110 may be disposed to be spaced apart from each other in the encapsulation member 20, and the encapsulation member 20 may surround the front surfaces of the solar cells 110.

In the present disclosure, the solar cell units 10 are installed in a horizontal arrangement that is perpendicular to a height direction of the encapsulation member 20 whereby it is not disturbed by interference from an angle of incidence of the sunlight and does not interfere with the field of vision of the user “U”.

Meanwhile, the solar cell units 10 may include the plurality of solar cell units 10 that are disposed to be spaced apart from each other in the height direction (the “Z” axis direction).

Here, it is preferable that the plurality of solar cell units 10 are disposed to be spaced apart from each other at equal intervals, and are installed in a horizontal arrangement within the encapsulation member 20 in a range that does not interfere with the field of vision of the user “U”.

Here, the horizontal arrangement may be defined as the angle defined by the height direction of the encapsulation member 20 standing upright in the height direction (the “Z” axis direction) and the upper surfaces of the solar cell units 10 being 30 to 90 degrees.

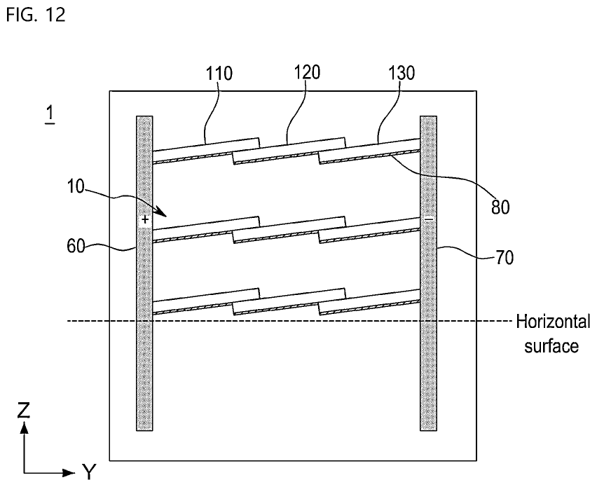

Meanwhile, referring to FIG. 12, the solar cell units 10 may be disposed horizontally on a horizontal plane. Through this, a uniform photoelectric efficiency may be achieved regardless of the incident direction of sunlight depending on the position of the sun.

Meanwhile, a reflector 180 may be disposed on the rear surface of the solar cell unit 10 to improve the photovoltaic efficiency by reflecting light input to the rear surface of the solar cell unit 10, and to prevent the solar cell unit 10 from being damaged by shading.

Here, the scattering part 30 may be disposed in the form of a plurality of nano particles in the encapsulation member 20, and may disperse the incident sunlight and condense it toward the solar cell unit 10, and through this, the photovoltaic efficiency may be improved.

The scattering part 30 may be a luminescent solar concentrator (LSC).

The first substrate 40 is formed in the form of a film and disposed on the rear side of the module, and thus serves to prevent moisture, contaminants, ultraviolet rays, and the like from being introduced into the rear surface of the module, and prevent electricity or heat from passing therethrough, thereby protecting the solar cells from the external environment. Accordingly, the first substrate 40 may be formed of a material having a durable property, such as a weather resistance, a moisture resistance, a insulation resistance, and a UV blocking properties, which may withstand a high temperature and humidity, a high voltage, and strong ultraviolet rays, and may have a multilayer structure, such as a layer that prevents penetration of moisture and oxygen, a layer that prevents chemical corrosion, and a layer that has insulating properties, and as an example, the first substrate 40 may be formed of polyvinyl fluoride (PVF) or polyvinylidene fluoride ((PVDF), polyethylene terephthalate (PET), or low iron tempered glass.

However, the first substrate 40 is not limited to these materials, and may be a transparent substrate like the second substrate 50.

The second substrate 50 is formed in the form of a film and disposed on a front side of the module, and may be formed of tempered glass with a high transmittance and an excellent damage prevention function to transmit incident light, or may be formed of a high-transmission fluorine film.

Then, the tempered glass may be low iron tempered glass with a low iron content.

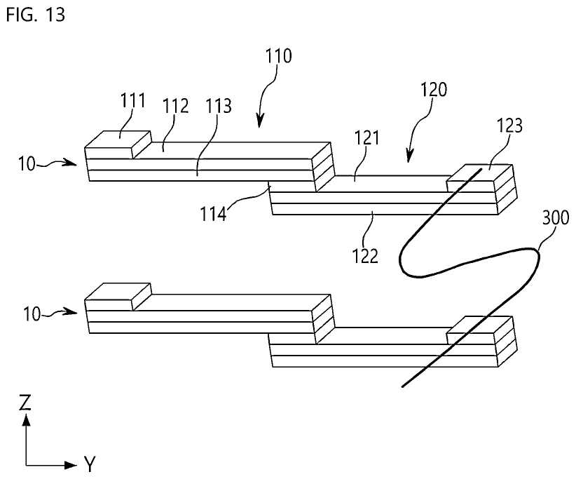

FIG. 13 is an exemplary view illustrating a photovoltaic module that is manufactured according to a second embodiment of the present disclosure.

Referring to FIG. 13, in the photovoltaic module manufactured according to the second embodiment of the present disclosure, a plurality of solar cell units 10 that are disposed to be spaced apart from each other in the height direction (the “Z” axis) may be connected to each other through a conductive member 300.

Here, each of the plurality of solar cell units 10 may include a first solar cell 110 and a second solar cell 120.

The first solar cell 110 may be disposed on one side in the horizontal direction (the “Y” axis), and may include a front electrode 111 (e.g., the − electrode), an n-type semiconductor layer 112, and a p-type semiconductor layer 113, and a rear electrode (114) (e.g., the + electrode) that are sequentially laminated.

Furthermore, the second solar cell 120 may be connected to the first solar cell 110 in the horizontal direction (the “Y” axis) and disposed on an opposite side, and the n-type semiconductor connected to the rear electrode 114 of the first solar cell 110, the p-type semiconductor layer 122 disposed on a lower side of the n-type semiconductor layer 121, and the terminal electrode 123 that is disposed on an upper side of the p-type semiconductor layer 122 to electrically connects the n-type semiconductor layer 121 and the conductive member 300.

The conductive member 300 may connect the terminal electrodes 123 of each of the plurality of solar cell units 10 disposed to be spaced apart from each other in the height direction (the “Z” axis).

That is, the conductive member 300 may connect the plurality of solar cell units 10 in a state, in which the p-type semiconductor layer and the + electrode, which are counter electrodes, are not in contact, and thus a shunt does not occur whereby an efficiency of the photovoltaic module may be improved.

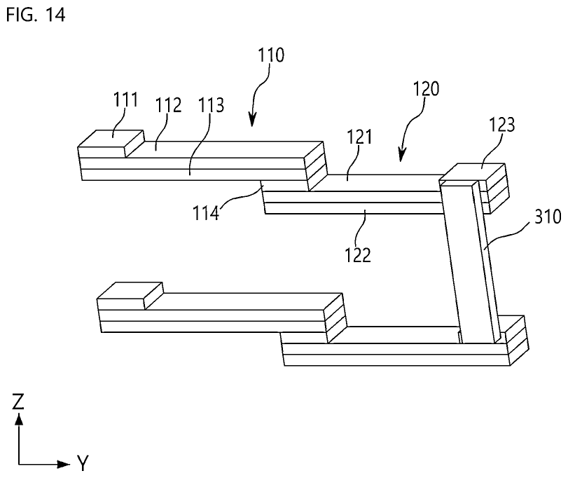

FIG. 14 is an exemplary view illustrating a photovoltaic module that is manufactured according to a third embodiment of the present disclosure.

The photovoltaic module manufactured according to the third embodiment has a different configuration of the conductive member 310 as compared with the photovoltaic module according to the third embodiment, and the conductive member 310 will be described in more detail hereinafter.

It is preferable that the photovoltaic module manufactured according to the third embodiment is configured such that a surface having a wide width is disposed on a front surface or a rear surface in a direction having a largest amount of light in the horizontal direction (the “Y” axis) such that shading that occurs due to the conductive member 310 is minimized as the sun moves.

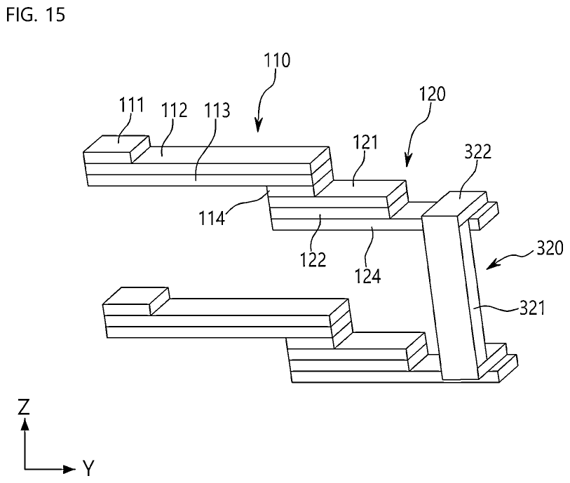

FIG. 15 is an exemplary view illustrating a photovoltaic module manufactured according to a fourth embodiment of the present disclosure.

Referring to FIG. 15, in the photovoltaic module manufactured according to the fourth embodiment of the present disclosure, a plurality of solar cell units 10 disposed to be spaced apart from each other in the height direction (the “Z” axis) may be connected to each other through a conductive member 320.

Here, each of the plurality of solar cell units 10 may include a first solar cell 110 and a second solar cell 120.

The first solar cell 110 may be disposed on one side in the horizontal direction (the “Y” axis), and may include a front electrode 111 (e.g., the − electrode), an n-type semiconductor layer 112, and a p-type semiconductor layer 113, and a rear electrode 114 (e.g., the + electrode) that are sequentially laminated.

Furthermore, the second solar cell 120 may be connected to the first solar cell 110 in the horizontal direction (the “Y” axis) and disposed on an opposite side, and may include an n-type semiconductor layer 121 connected to the rear electrode 114 of the first solar cell 110, a p-type semiconductor layer 122 disposed on a lower side of the n-type semiconductor layer 121, and a rear electrode 124 disposed on a lower side of the p-type semiconductor layer 122, connected to the p-type semiconductor layer 122, and extending to the opposite as compared with the p-type semiconductor layer 122.

The conductive member 300 may connect the rear electrodes 123 of each of the plurality of solar cell units 10 disposed to be spaced apart from each other in the height direction (the “Z” axis).

Here, the conductive member 320 may include a body 321 that extends in the height direction (the “Z” axis) and a bent part 322 that is bent from the body 321 to expand a contact area with an upper surface of the rear electrode 124.

That is, the conductive member 320 may be electrically connected only to the rear electrode 124 that is the + electrode, and may connect the plurality of solar cell units 10 in a state, in which the n-type semiconductor layer 121 and the − electrode that are counter electrodes are not in contact, and thus, a shunt does not occur whereby the efficiency of the photovoltaic module may be improved.

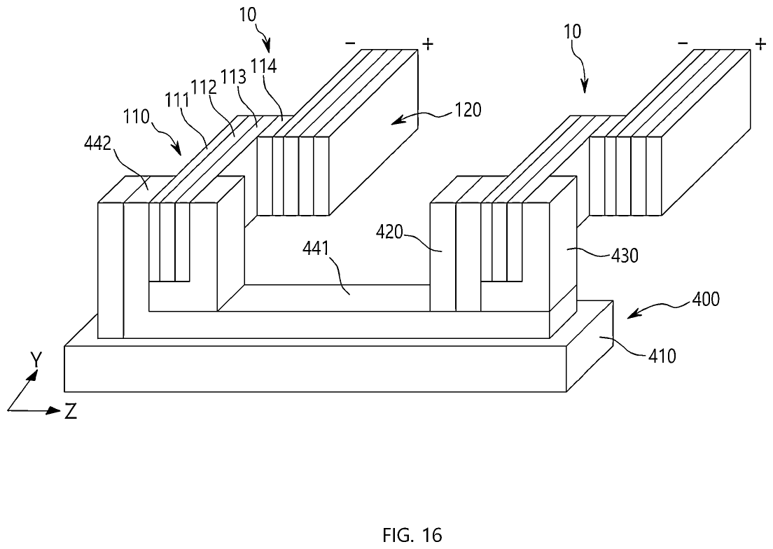

FIG. 16 is an exemplary view illustrating a photovoltaic module manufactured according to a fifth embodiment of the present disclosure.

Referring to FIG. 16, in the photovoltaic module manufactured according to the fifth embodiment of the present disclosure, a plurality of solar cell units 10 disposed spaced apart from each other in the height direction (the “Z” axis) may be connected to each other through a conductive member 400.

Here, each of the plurality of solar cell units 10 may include a first solar cell 110 that is disposed on one side in the horizontal direction (the “Y” axis), and a second solar cell that is electrically connected to the first solar cell 110 and is disposed on an opposite side to extend.

The first solar cell 110 may include a front electrode 111, an n-type semiconductor layer 112, a p-type semiconductor layer 113, and a rear electrode 114 that are sequentially laminated.

The conductive member 400 may include a support part 410 that extends in the height direction (the “Z” axis), a plurality of grips 420 and 430 that extend from the support part 410 toward the solar cell unit 10, and grip the first solar cell 110, and conductive parts 441 and 442 that are electrically connected to the front electrode 111 of the first solar cell 110.

The conductive parts 441 and 442 may include a first conductive part 441 that extends in the height direction (the “Z” axis) along the support part 410, and a second conductive part 442 that is bent from the first conductive part 441 to extend along the grip part 420 and contact the front electrode 111 of the first solar cell 110.

That is, the conductive member 400 is one, into which the plurality of solar cell units 10 are inserted, and may connect the plurality of solar cell units 10, and each of the second conductive parts 442 may electrically contact only the front electrode 111 of the first solar cell 110 in the conductive member 400, and thus a shunt does not occur whereby the efficiency of the photovoltaic module may be improved.

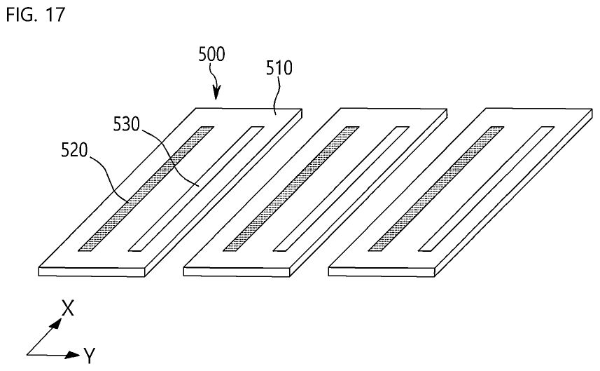

FIGS. 17 to 20 are exemplary views illustrating a photovoltaic module that is sequentially manufactured according to a sixth embodiment of the present disclosure.

First, referring to FIG. 17, in a method of manufacturing a photovoltaic module according to the sixth embodiment of the present disclosure, a plurality of semiconductor substrates 510 disposed in a row in the first direction (the “Y” axis direction) is prepared, and an n-type semiconductor doping area 520 and a p-type semiconductor doping area 530 are formed on each of the semiconductor substrates 510 along the first direction.

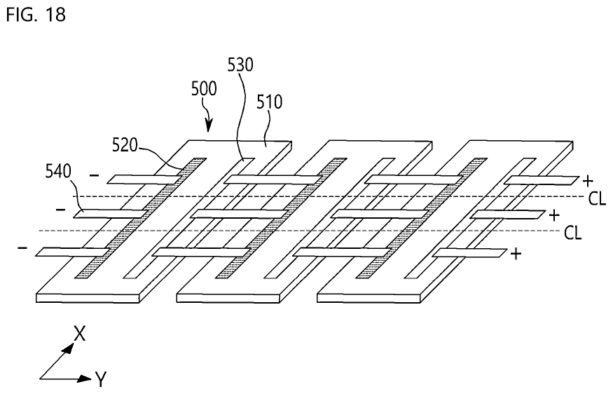

Thereafter, referring to FIG. 18, a conductive member 540 that electrically connects the p-type semiconductor doping area 530 of the semiconductor substrate 510 and the n-type semiconductor doping area 520 of the adjacent semiconductor substrate 510 may be disposed to form a solar cell assembly. Here, the conductive member 540 may connect the n-type semiconductor doping area 520 and the p-type semiconductor doping area 530 in series between the adjacent semiconductor substrates 510.

Meanwhile, the conductive member 540 may include a metal core that constitutes an electrode and a solder layer that surrounds the metal core.

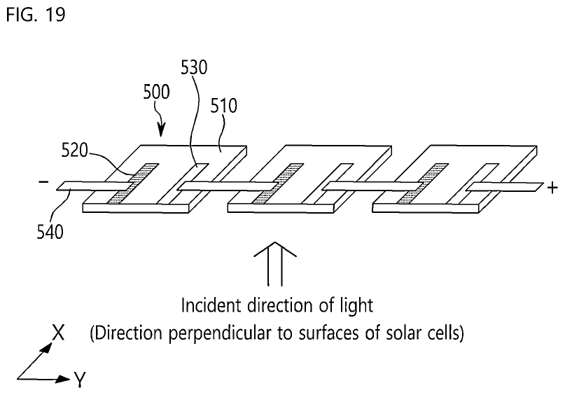

Thereafter, referring to FIGS. 18 and 19, a plurality of solar cell units may be formed by cutting with a plurality of cutting lines CL that are formed along the first direction (the “Y” axis direction).

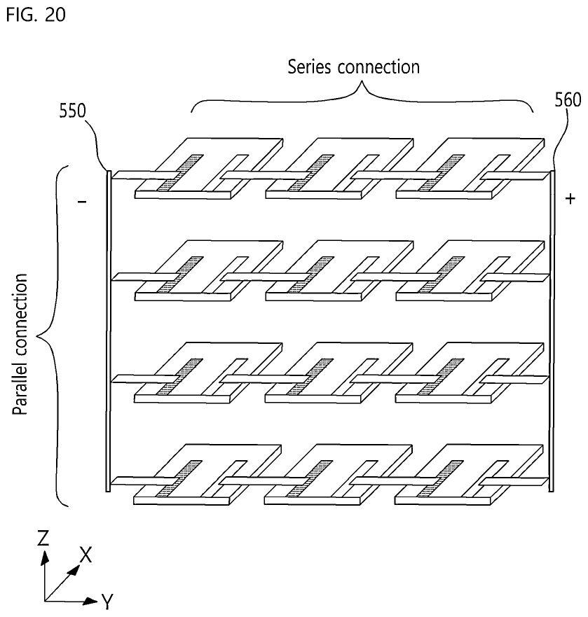

Referring to FIG. 20, the plurality of solar cell units may be disposed in the encapsulation member such that the angles defined by the height direction of the encapsulation member (not illustrated) and the upper surfaces of the solar cell units are 30 degrees to 90 degrees. Furthermore, terminals, such as ribbons or bus bars, may be disposed at opposite ends of the solar cell units by connecting the solar cell units in parallel.

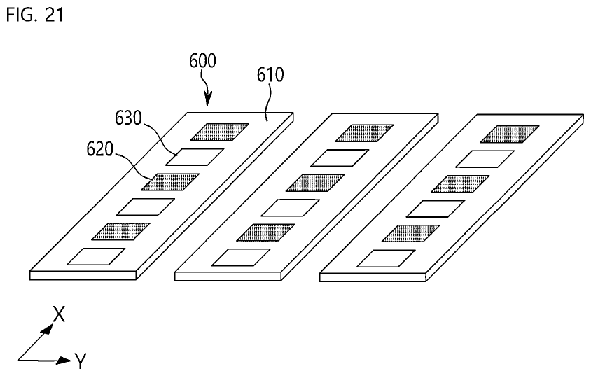

FIGS. 21 to 24 are exemplary views illustrating a photovoltaic module that is sequentially manufactured according to a seventh embodiment of the present disclosure.

First, referring to FIG. 21, in a method for manufacturing a photovoltaic module according to the seventh embodiment of the present disclosure, a plurality of semiconductor substrates 610 disposed in a row in the first direction (the “Y” axis direction), are prepared, and an n-type semiconductor doping area 620 and a p-type semiconductor doping area 630 are formed on each of the semiconductor substrates 610 along the second direction (the “X” axis direction) that is perpendicular to the first direction.

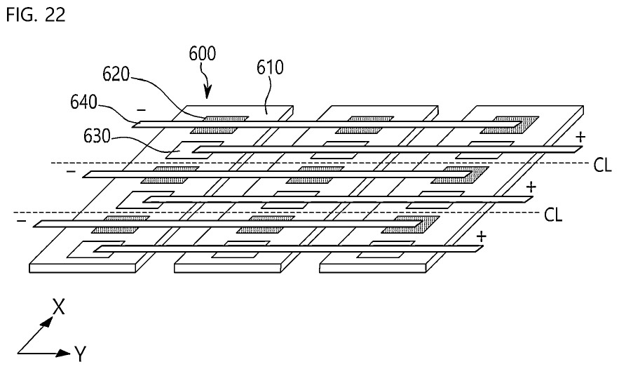

Thereafter, referring to FIG. 22, a solar cell assembly may be formed by disposing the n-type semiconductor doping area 620 and the p-type semiconductor doping area 630 of the semiconductor substrate 610, and a conductive member 640 that electrically connects the n-type semiconductor doping area 620 and the p-type semiconductor doping area 630 of the semiconductor substrate 610 adjacent thereto. Here, the conductive members 640 may connect the n-type semiconductor doping area 620 and the p-type semiconductor doping area 630 in parallel between the adjacent semiconductor substrates 610.

Meanwhile, the conductive member 640 may include a metal core that constitutes an electrode and a solder layer that surrounds the metal core.

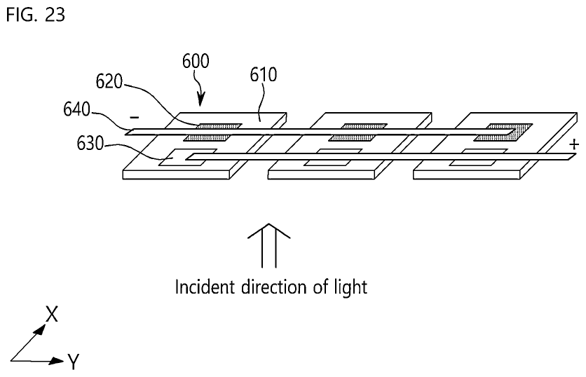

Thereafter, referring to FIGS. 22 and 23, a plurality of solar cell units may be formed through cutting with a plurality of cutting lines CL that are formed along the first direction (the “Y” axis direction).

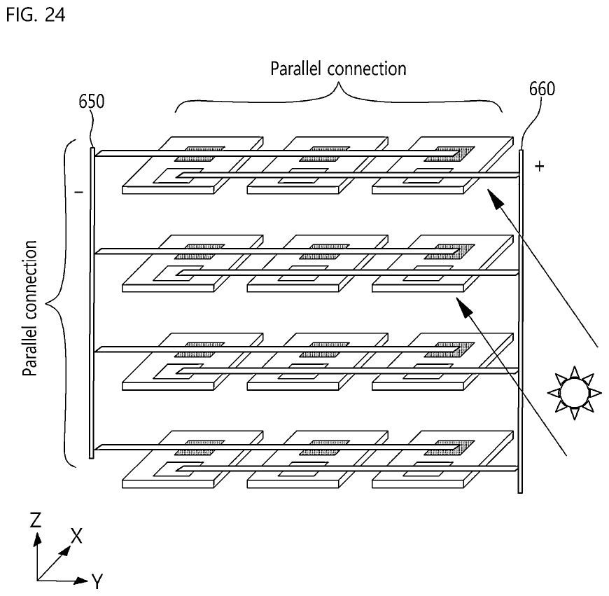

Thereafter, referring to FIG. 24, the plurality of solar cell units may be disposed in the encapsulation member such that the angles defined by the height direction of the encapsulation member (not illustrated) and the upper surfaces of the solar cell units are 30 to 90 degrees. Furthermore, terminals, such as ribbons or bus bars, may be disposed at opposite ends to connect the solar cell units in parallel.

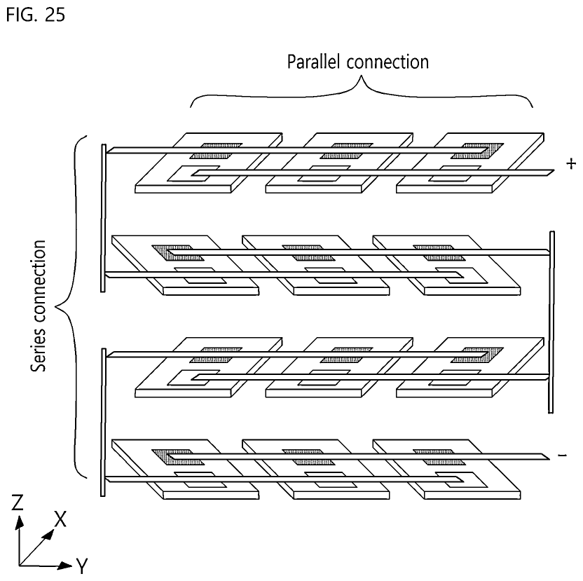

FIG. 25 is an exemplary view illustrating a photovoltaic module that is manufactured according to an eighth embodiment of the present disclosure.

Meanwhile, the photovoltaic module manufactured according to the seventh embodiment of the present disclosure illustrated in FIG. 24 has the plurality of solar cell units that are connected to each other in parallel, but the photovoltaic module manufactured according to the eighth embodiment of the present disclosure illustrated in FIG. 25 has a plurality of solar cell units that are connected to each other in series.

The above detailed description is illustrative of the present disclosure. Furthermore, the foregoing is intended to illustrate preferred embodiments of the present disclosure, and the present disclosure may be used in various other combinations, modifications, and environments. That is, changes or modifications may be made within the scope of the inventive concept disclosed in this specification, a scope equivalent to the written disclosure, and/or within the scope of technology or knowledge in the art. The written embodiments illustrate the best state for implementing the technical idea of the present disclosure, and various changes required for specific application fields and uses of the present disclosure are also possible. Accordingly, the detailed description of the present disclosure above is not intended to limit the present disclosure to the disclosed embodiments. Additionally, the appended claims should be construed to include other embodiments as well.

### DESCRIPTION OF REFERENCE NUMERALS

1: photovoltaic module
10: solar cell units
110: solar cells

1. A method for manufacturing a photovoltaic module, the method comprising:
forming a solar cell assembly by connecting a plurality of solar cells in an alignment direction in series;
forming a plurality of solar cell units by cutting the solar cell assembly along a cutting line in a direction being different from the alignment direction; and
disposing the plurality of solar cell units in an encapsulation member such that angles defined by a height direction of the encapsulation member and upper surfaces of the solar cell units are 30 degrees to 90 degrees.

2. The method of claim 1, wherein the forming of the solar cell assembly includes:
forming joining parts in joining areas of the adjacent solar cells; and
connecting the plurality of solar cells in the alignment direction in series.

3. The method of claim 2, wherein in the forming of the joining parts, each of the joining parts has a plurality of ball shapes disposed to be spaced apart from each other.

4. The method of claim 3, wherein in the forming of the joining parts, the joining parts are not disposed in an area, through which the cutting line passes, in the forming of the plurality of solar cell units.

5. The method of claim 4, wherein in the forming of the joining parts, the joining parts are spaced apart from the area of the cutting line.

6. The method of claim 1, wherein the plurality of solar cell units are connected to each other in parallel through a pair of terminals.

7. The method of claim 6, wherein the solar cell units are arranged in parallel to a horizontal surface.

8. The method of claim 6, further comprising:
electrically connecting the solar cell units spaced apart from each other in the height direction through conductive members.

9. The method of claim 8, wherein the solar cell units include a first solar cell disposed on one side, and a second solar cell electrically connected to the first solar cell and disposed on an opposite side to extend,
wherein the first solar cell includes a front electrode, an n-type semiconductor layer, a p-type semiconductor layer, and a rear electrode, which are sequentially laminated, and
wherein the second solar cell includes an n-type semiconductor layer connected to the rear electrode of the first solar cell, a p-type semiconductor layer, and a terminal electrode connecting the n-type semiconductor layer and the conductive member.

10. The method of claim 8, wherein the solar cell units include a first solar cell disposed on one side, and a second solar cell electrically connected to the first solar cell and disposed on an opposite side to extend,
wherein the first solar cell includes a front electrode, an n-type semiconductor layer, a p-type semiconductor layer, and a rear electrode, which are sequentially laminated,
wherein the second solar cell includes an n-type semiconductor layer connected to the rear electrode of the first solar cell, a p-type semiconductor layer, and a terminal electrode connecting the p-type semiconductor layer and the conductive member, and
wherein an opposite end of the terminal electrode extends to an opposite side of an opposite end of the p-type semiconductor layer.

11. The method of claim 8, wherein each of the plurality of solar cell unit includes a first solar cell disposed on one side, and a second solar cell electrically connected to the first solar cell and disposed on an opposite side to extend,
wherein the first solar cell includes a front electrode, a n-type semiconductor layer, a p-type semiconductor layer, and a rear electrode, which are sequentially laminated, and
wherein the conductive member includes a support part extending in a height direction, a plurality of grip parts extending from the support part to the solar cell units, and a plurality of grip parts configured to grip the first solar cell, and a conductive part electrically connected to the front electrode of the first solar cell.

12. A method for manufacturing a photovoltaic module, the method comprising:
forming an n-type semiconductor doping area and a p-type semiconductor doping area in each of a plurality of semiconductor substrates;
forming a solar cell assembly by disposing a plurality of semiconductor substrates in a row in an alignment direction, and then connecting an n-type semiconductor doping area and a p-type semiconductor doping area between adjacent semiconductor substrate in series or parallel;
forming a plurality of solar cell units each having an n-type semiconductor doping area and a p-type semiconductor doping area by cutting the solar cell assembly along a cutting line in a direction being different from the alignment direction; and
disposing the plurality of solar cell units in an encapsulation member such that angles defined by a height direction of the encapsulation member and upper surfaces of the solar cell units are 30 degrees to 90 degrees.
